(19) United States
(12) Patent Application Publication
(10) Pub. No.: US 2016/0160314 A1
(43) Pub. Date: Jun. 9, 2016

(54) APPARATUS AND METHOD FOR SEQUENTIAL MELTING AND REFINING IN A CONTINUOUS PROCESS

(71) Applicant: ALD VACUUM TECHNOLOGIES GMBH, Hanau (DE)

(72) Inventors: Henrik FRANZ, Freigericht (DE); Arno NIEBLING, Linsengericht (DE); Ulrich BIEBRICHER, Niddatal (DE)

(21) Appl. No.: 14/903,725

(22) PCT Filed: Jul. 17, 2014
(86) PCT No.: PCT/EP2014/065429

§ 371 Date: Jan. 8, 2016

(30) Foreign Application Priority Data
Jul. 18, 2013 (DE) 10 2013 107 685.8

(51) Int. Cl. C22B 9/22; H01J 37/32; F27B 19/02; F27D 11/12; F27D 11/06; F27D 3/14; H01J 37/305; F27D 11/08

(52) U.S. Cl. CPC C22B 9/226; C22B 9/228; H01J 37/305; H01J 37/32009; F27D 11/08; F27D 11/12; F27D 11/06; F27D 3/14; F27B 19/02

(57) ABSTRACT

An apparatus and a method performable with the apparatus for sequential melting and refining of materials are proposed. The materials treated in the process are converted to a liquid state of matter by heat sources. The process is particularly suitable for treating metals, semimetals and ceramics, for example in order to produce alloys and/or to refine the materials. During the method, the material goes through various treatment chambers which enable treatment at different pressure levels.

### FIELD OF THE INVENTION

This invention relates to an apparatus and a method performable with the apparatus for sequential melting and refining of materials. The materials treated in the process are converted to a liquid state of matter by one or more heat sources or are already in such a state before the treatment. The process is particularly suitable for treating metals, metalloid and ceramics, for example in order to produce alloys and/or to refine the materials.

### BACKGROUND OF THE INVENTION

From prior art numerous methods with which materials can be heated are known. Such a method is the electron beam method during which an electron beam is directed onto a material for generating heat in the material in a targeted manner. This method is particularly flexible, since a certain portion of the material can be heated to very high temperatures in a targeted manner. If larger portions of material should be heat-treated, the electron beam can be scanned over the material to be heated.

The electron beam melting method can only be conducted under vacuum. The inherent conduction of the method under vacuum results in the advantage that impurities which are optionally present in the material can be removed. The material will be refined. On the other hand, due to the vacuum with the electron beam method also the composition of the material can be changed by evaporation of volatile constituents, which may be advantageous for example in the case of refining. This evaporation of volatile constituents naturally occurs in a particularly strong manner in the case of material mixtures which are non-homogeneous, for example in the case of mixtures of metal swarf and cuttings and additives which are not melted. The evaporation may be desired or it may be a problem when the original composition should be maintained. Of course, this problem also occurs in the case of other melting and refining processes which are conducted under vacuum at temperatures of >500° C.

Another method which is known from prior art is plasma melting during which the material is heated at pressures which are considerably higher than 1 mbar, in particular higher than 100 mbar. Plasma melting is well suitable for the melting of many materials.

There are numerous methods for melting and refining of materials at reduced pressure and/or under conditions of vacuum. In an exemplary manner the methods can be classified in three categories: the high vacuum methods are methods which are conducted in a pressure range of between 10⁻⁷ mbar and 10⁻² mbar. The vacuum methods are methods which are conducted in a pressure range of between 10⁻² mbar and 100 mbar. The low pressure methods are conducted in a pressure range of between 100 mbar and 1 atm.

When a melt has to be treated consecutively at different pressures and when the heating processes used in these methods only work efficiently in the respective pressure range, then it is necessary to conduct this treatment in a batch process today. For example, the material has to be removed from a crucible and has to be transferred into another one between the treatment steps. Often, a continuous treatment with different methods is desired. In the case of refining a material, for example, it may be necessary to remove one or more impurities in a pressure range of >100 mbar, when this impurity has to be reacted with a reactive gas such as e.g. oxygen for becoming volatile. In a second step it may be necessary to apply a high vacuum for removing volatile impurities. It is obvious that such a sequential treatment cannot easily be conducted in a continuous method. In particular, it would be connected with a high instrument-based effort, since the levels of the melt would be different depending on the respective pressure. According to the density of the melt this may easily result in a level difference of some meters. A corresponding facility would occupy much space and thus would be uneconomic.

DE 1 291 760 A describes a method in which at first a base batch of a metal is heated by means of electron beam heating in vacuum. Volatile alloy constituents are added afterwards and heated with plasma jet. However, the treatment of the metal is conducted in one single treatment vessel in which the respective melt is consecutively heated with different methods at different pressures. A continuous conduction of the method is only possible, when a very complex facility is used. In addition, the method described there requires a sequential addition of alloy constituents, which is preferably excluded according to the present invention. In addition, pressure differences are not used for the transport of the material, because the transfer channel does not open out into the second process vessel, but ends above the level of the melt in the second vessel. Furthermore, the transport of the melt through the transfer channel is not achieved by moving electromagnetic fields.

DE 2 118 894 C2 teaches a transport of the melt by means of an electromagnetic pump, but no deceleration or stop of the flow is disclosed.

In U.S. Pat. No. 5,503,655 A no electromagnetic manipulation of the flow of the material is mentioned. In particular, no deceleration or stop of the flow is described.

In U.S. Pat. No. 4,027,722 A a very simple system for heating a metal melt with an electron beam method is described. An electromagnetic manipulation of the flow rate is not mentioned. Instead of that the pressure difference between the chambers is used for conveying the melt through a pipe 26 (FIG. 1).

Thus, there is a need for combining the advantages of high vacuum methods, vacuum methods and low pressure methods in a continuous process without increasing the required instrument-based effort too much.

### SUMMARY OF THE INVENTION

This invention provides such a method and a respective apparatus.

The method comprises the following steps

a liquid material is melted and/or refined at different pressures in different treatment chambers, wherein the separation of the pressure levels is effected by the liquid material itself,

the liquid material is transferred from a first treatment chamber into another second treatment chamber, wherein the transfer of the material is achieved by pressure differences in combination with electromagnetic manipulation of the flow rate between the treatment chambers, and

the heat sources used in the treatment chambers work independently of each other,

wherein the electromagnetic manipulation is effected by the use of means which create a moving electromagnetic field and that the manipulation comprises a deceleration and/or a stop of the flow of the liquid material,

and that the pressure in the second treatment chamber is lower than the pressure in the first treatment chamber.

The requirement that the at least two heat sources work independently of each other means, preferably, that these heat sources are different heat sources or that they are equal heat sources working at different pressures. Preferably, one heat source is a plasma burner and the other heat source is an electron beam gun or both heat sources are electron beam guns or both heat sources are plasma burners working at different pressures.

The electromagnetic manipulation of the flow rate is achieved by the use of means that are capable of creating a moving electromagnetic field. With these means the flow of the liquid material can be started, accelerated, decelerated or even stopped. By the deceleration or stop of the flow of the material level differences of the melts in the different treatment chambers caused through the pressure difference can be reduced and/or avoided. Preferable means are one or more coils, in particular segmented coils and/or a plurality of sequential coils being arranged along a transfer channel. The method for sequential heat treatment according to the present invention is particularly suitable for the production of alloys and/or for refining. It may comprise one or more of the following steps:

introducing the material to be treated into the first treatment chamber,

heating and/or refining the material so that the material is converted into or remains in a liquid state or is refined,

transferring the liquid material into the second treatment chamber,

heating and/or refining the liquid material in the second treatment chamber.

In a treatment chamber, in particular in the first one, the treatment of the material is preferably conducted at a pressure of >10 mbar, further preferably >100 mbar, more preferably >300 mbar, more preferably >500 mbar and particularly preferably >800 mbar. In the other treatment chamber, in particular in the second one, the pressure is preferably lower, wherein the pressure there is in particular only up to 10 mbar, preferably up to 1 mbar, further preferably up to 0.1 mbar and particularly preferably up to 0.01 mbar.

Preferably, the transfer of the liquid material from the one treatment chamber into the other treatment chamber is achieved by a transfer channel allowing a continuous flow of the liquid material. Thus, the method can be conducted in a continuous manner. Of course, also a semi-continuous or batch method is possible, but due to economic reasons such methods are less preferred.

Preferably, the transfer channel facilitates the transfer of the liquid material from the first into the second treatment chamber. The transfer of the liquid material is achieved, inter alia, due to pressure differences between the treatment chambers. The liquid material flows along the pressure gradients and/or mediated by the electromagnetic manipulation of the liquid material from the first into the second treatment chamber. The pressure in the second treatment chamber is lower than the pressure in the first treatment chamber so that the liquid material by a present pressure gradient preferably in combination with a present level difference is conveyed in a targeted manner. In this case the method is preferably conducted such and/or the apparatus is designed such that during operation the transfer channel is completely filled with material. Thus, it is facilitated that the different pressures in the treatment chambers are maintained.

The treatment chambers are preferably designed such that they can be hermetically sealed with respect to the environment so that the process pressure can be adjusted correspondingly. This, in particular, applies to the treatment chamber with the lower pressure. Either, the treatment chambers can be completely separated treatment chambers, or they can be created by the division of a large chamber into two treatment chambers, such as for example by the insertion of a separating element, such as a separating wall, into the large chamber.

In the treatment chambers a process vessel, in particular a crucible or a tank, can be arranged in which during the process the material is present. But the process vessel can also be designed such that it is a part of the treatment chamber or that it is identical with the treatment chamber. Preferably, each treatment chamber contains one process vessel. In an alternative embodiment a process vessel extends from one treatment chamber into the other one, wherein the transfer channel can be an opening in the separating element.

For the introduction of the material to be treated into the first treatment chamber the apparatus according to the present invention preferably comprises a feed facility which allows a continuous introduction of the material into the first treatment chamber. Such a feed facility may, for example, be a conveying trough.

After the conduction of the method according to the present invention the treated material can be removed from the second treatment chamber. For this purpose the apparatus preferably comprises a discharge device which allows discharging of the material. When the second treatment chamber operates at a process pressure which is lower than ambient pressure, then it is advantageous to perform the discharge of the treated material in such a manner that the low pressure in the chamber is maintained. This may preferably be realized by a design of the discharge device as an outflow. In an alternative embodiment in the treatment chamber with lower pressure a collecting basin for the treated material is present so that the basin can remain in the treatment chamber till its removal.

The transfer channel is a connection between both treatment chambers. Preferably, it is heated, such as for example with an induction heater or a burner, so that the liquid material does not solidify. In embodiments without any heating of the transfer channel the treatment chambers should be located very near to each other, when material with a high melting point and/or an unfavorable viscosity-temperature-profile is utilized. Preferably, the transfer channel comprises two openings, a proximal one and a distal one. Through the proximal opening the liquid material from the first treatment chamber can enter into the transfer channel, and through the distal opening it can exit from the transfer channel into the second treatment chamber.

The proximal opening of the transfer channel can be arranged such that the liquid material from the first treatment chamber or the first process vessel falls down into the transfer channel. Thus it is not necessary that the first treatment chamber or the first process vessel is connected with the transfer channel. Preferably, the proximal opening of the transfer channel is located in the lower region of the first treatment chamber or, when the treatment chamber is not also the process vessel, in the lower region of the first process vessel. This was shown to be advantageous, since feeding of material to be treated can be conducted in the easiest manner from above and also heating is preferably conducted from above. Thus, ideally in the lower region of the first treatment chamber the material is already in a liquid state which is sufficient so that it is capable of flowing through the transfer channel. The distal opening opens out into the second treatment chamber, in particular in its lower region, or, when the treatment chamber is not also the process vessel, into the lower region of the process vessel. It, in particular, opens out into a region of the second treatment chamber which is below the level of the melt in this treatment chamber.

The level of the liquid material in one treatment chamber is preferably higher than the level in the other treatment chamber. This level difference in particular results from the different process pressures in both chambers. Due to this reason the second treatment chamber or the second process vessel is preferably arranged in a higher position than the first treatment chamber or the first process vessel. But this difference in height can be much smaller than in prior art, since according to the present invention countermeasures can be taken.

The melting and refining processes in the first treatment chamber are preferably conducted by use of a low pressure method, in particular by a plasma melting method.

In the first treatment chamber the material is preferably heated to temperatures of 1000 to 3000° C., further preferably 1200 to 2500° C., particularly preferably 1400 to 2000° C. Optionally, reactive gases (e.g. oxygen, hydrogen, nitrogen) or inert gases (e.g. argon, helium) can be introduced. For this purpose the apparatus according to the present invention preferably comprises a gas inlet, in particularly for being able of introducing gasses into the first treatment chamber in a controlled manner. The treatment chamber with the lower pressure does preferably not comprise such gas inlets.

The melting and refining processes in the second treatment chamber are preferably conducted by the use of a high vacuum method or vacuum method, in particular by an electron beam method.

In the second treatment chamber the material is preferably heated to temperatures of 1000 to 4000° C., further preferably 1200 to 3800° C., particularly preferably 1400 to 3500° C. Preferably, no reactive gas is introduced or only low amounts of gas are used which are not an obstacle for the maintenance of the operating pressure.

The material to be treated preferably comprises metals, metalloids, ceramics or mixtures thereof. Preferably, the material to be treated is substantially a metallic material, a semimetallic material and/or a material which in the liquid state is characterized by a sufficiently high electric conductivity. Preferable materials to be treated are titanium and silicon; but also steels, reactive and refractory metals or composite materials comprising ceramics can be used.

So that the material can advantageously be used in the method according to the present invention, it has preferably a conductivity in the liquid state of at least 1*10² S/m. Preferably, at normal pressure the material to be treated has a melting point of >1000° C.

Depending on the material to be treated the material to be melted may contain impurities which are removed under the different conditions of the method. Examples of impurities which may be contained in the material to be melted are boron and phosphorus.

In a particularly preferable embodiment the material to be treated comprises silicon, in particular in a proportion of higher than 95% (w/w). For the treatment of silicon the material is heated in the first treatment chamber for removing impurities, wherein under the conditions according to the present invention, for example, boron can be removed; and thereafter the silicon is transferred as a liquid melt over the transfer channel into the second treatment chamber, where due to the low pressure also other impurities, such as for example phosphorus, can be removed.

The apparatus which is also part of the present invention is suitable for conducting the method. Preferably, the apparatus comprises

a first treatment chamber,

a second treatment chamber and

a transfer channel which connects both chambers with each other,

wherein both treatment chambers each comprise at least one heat source. Preferably, the heat sources work independently from each other and can be controlled independently from each other. Preferably, the transfer channel is arranged such that it rises from one treatment chamber to the other treatment chamber. The apparatus comprises means for electromagnetic manipulation of the flow rate. These means manipulate the flow rate of a liquid conductive material being present in the transfer channel. These means are devices which are capable of creating moving electromagnetic fields. They are preferably one or more coils, in particular segmented coils. The means are preferably arranged around the transfer channel. But besides coils also other means with which electromagnetic fields can be generated facilitating a manipulation of the flow rate in the sense of a magneto-hydrodynamic manipulation are possible.

The first treatment chamber comprises a heat source which is selected from a plasma burner and an electron beam gun, while the second treatment chamber comprises an electron beam gun as a heat source.

### DESCRIPTION OF THE FIGURES

The embodiments illustrated in the figures show exemplary embodiments of the invention.

FIG. 1 shows an apparatus in accordance with the present invention comprising two treatment chambers 1 and two process vessels 2. It can be seen that each treatment chamber 1 contains one process vessel 2. In the process vessels the material to be treated 3 is present which has to be liquid, at the latest when it enters into the transfer channel 4. Two heat sources 5 and 6 which are different are shown. Heat source 5 may, for example, be a plasma burner, and heat source 6 may, for example, be an electron beam gun. It can be seen that the level of the liquid material in the second treatment chamber is higher than the level in the first one. Thus, the liquid material has to rise in the transfer channel 4. This is caused by a pressure difference, because the plasma burner works in this example in the range of low pressures, while the electron beam gun works in vacuum. The arrows show the direction of the flow of the liquid material. The liquid material completely fills the transfer channel 4 so that the pressure levels in both chambers can be maintained. The feed facility 7 supplies new material to be treated so that a continuous process is possible. Basin 8 collects the treated material.

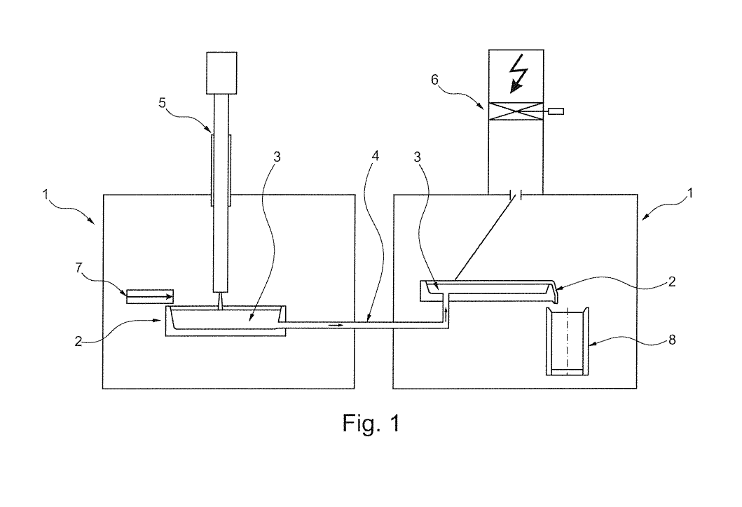

FIG. 2 shows an apparatus according to the present invention comprising one large chamber 1 which is separated into two treatment chambers by the use of a separating wall 9. Only one process vessel 2 which extends over both chambers is present. In the process vessel the material to be treated 3 is present which has to be liquid, at the latest when entering into the transfer channel 4. Here the transfer channel is very short. This results in the advantage that the liquid material is only slightly cooled, when it enters from one into another treatment chamber. Two heat sources 5 and 6 which are different are shown. Heat source 5 may, for example, be a plasma burner, and heat source 6 may, for example, be an electron beam gun. It can be seen that the level of the liquid material in the second treatment chamber is higher than that in the first one. This is caused by a pressure difference, because the plasma burner works in this example in the range of low pressures, while the electron beam gun works in vacuum. The liquid material completely fills the transfer channel 4 so that the pressure levels in both chambers can be maintained. The feed facility 7 supplies new material to be treated so that a continuous process is possible. Basin 8 collects the treated material.

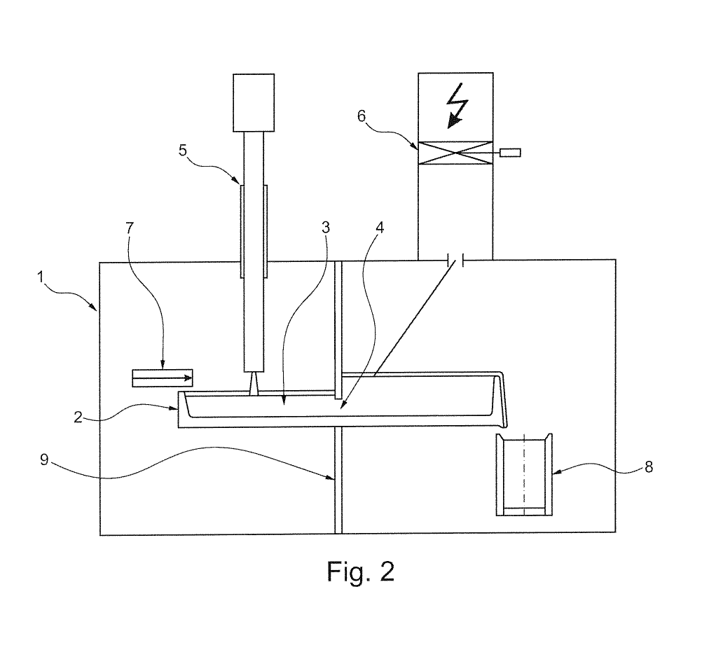

FIG. 3 shows an apparatus according to the present invention comprising two treatment chambers 1 and two process vessels 2. It can be seen that each treatment chamber 1 contains one process vessel 2. In the process vessels the material to be treated 3 is present which has to be liquid, at the latest when it enters into the transfer channel 4. Two heat sources 5 and 6 which are different are shown. Heat source 5 may, for example, be a plasma burner, and heat source 6 may, for example, be an electron beam gun. It can be seen that the level of the liquid material in the second treatment chamber is higher than the level in the first one. Thus, the liquid material has to rise in the transfer channel 4. This is caused by a pressure difference, because the plasma burner works in this example in the range of low pressures, while the electron beam gun works in vacuum. The arrows show the direction of the flow of the liquid material. The liquid material completely fills the transfer channel 4 so that the pressure levels in both chambers can be maintained. The feed facility 7 supplies new material to be treated so that a continuous process is possible. Basin 8 collects the treated material. For controlling the flow rate of the liquid material through the transfer channel 4, the apparatus comprises a means for magneto-hydrodynamic regulation of the flow, such as for example coils 10. Here the proximal opening of the transfer channel is arranged such that the liquid material falls down from the first process vessel into the transfer channel.

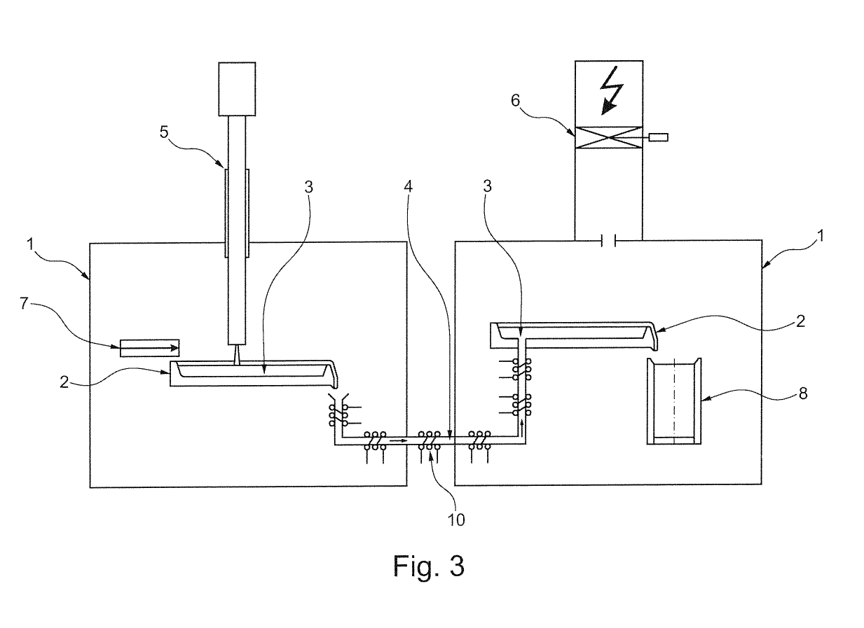

### LIST OF REFERENCE SIGNS

1 treatment chamber
2 process vessel
3 material to be treated
4 ‘transfer channel
5 heat source A
6 heat source B
7 feed facility
8 collecting basin
9 separating wall
10 coil

What is claimed is:

1. A method for sequential treatment of a material, wherein
a liquid material is melted and refined at different pressures in different treatment chambers, wherein the separation of the pressure levels is effected by the liquid material itself so that a continuous process is possible,
the liquid material is transferred from a first treatment chamber into another second treatment chamber, wherein the transfer of the material is achieved by pressure differences in combination with electromagnetic manipulation of the flow rate between the treatment chambers, and
the heat sources used in the treatment chambers work independently from each other,
wherein the electromagnetic manipulation is effected by the use of means which create a moving electromagnetic field and that the manipulation comprises a deceleration and/or a stop of the flow of the liquid material,
and that the pressure in the second treatment chamber is lower than that in the first treatment chamber.

2. The method according to claim 1, wherein the transfer of the melt from the first treatment chamber into the second one is conducted in a channel which may be designed such that it can be heated.

3. The method according to claim 1, comprising the steps:
introducing the material to be treated into the first treatment chamber,
heat-treating the material in the first treatment chamber at a pressure of >10 mbar so that the material is converted into or maintained in a liquid state,
transferring the liquid material into the second treatment chamber,
heat-treating of the liquid material in the second treatment chamber at a pressure of up to 10 mbar,
wherein the transfer of the liquid material from the first treatment chamber into the second treatment chamber is conducted by a transfer channel which connects both treatment chambers and facilitates a continuous flow of the liquid material.

4. The method according to claim 1, wherein the heat source in the second treatment chamber is an electron beam gun.

5. The method according to claim 1, wherein the material to be treated comprises at least a metal, metalloid or a ceramic.

6. The method according to claim 1, wherein the material to be treated comprises silicon.

7. The method according to claim 1, wherein the electromagnetic manipulation of the flow rate in the transfer channel is effected by at least one coil which is arranged around the transfer channel.

8. The method according to claim 1, wherein the melt after the conducted treatment is subjected to a further treatment in the liquid state or is fed into a separate apparatus in the liquid state for solidification and is solidified there.

9. The method according to claim 1, wherein the solidification of the melt after the treatment is effected as block removal from an inductively heated water-cooled copper crucible.

10. The method according to claim 1, wherein one heat source is a plasma burner and another heat source is an electron beam gun or both heat sources are electron heat guns or both heat sources are plasma burners which work at different pressures.

11. The method according to claim 1, wherein the material in the first treatment chamber is heated to temperatures of 1000° C. to 3000° C. and/or the material in the second treatment chamber is heated to temperatures of 1000° C. to 4000° C.

12. An apparatus for conducting a method according to claim 1, comprising
a first treatment chamber,
a second treatment chamber and
a transfer channel which connects both chambers with each other,
wherein both treatment chambers are provided with at least one heating facility each and a means for electromagnetic manipulation of the flow rate of a liquid conductive material is provided in the transfer channel, wherein the means creates a moving electromagnetic field and the flow of the liquid material is decelerated and/or stopped,
wherein the first treatment chamber comprises a heat source which is selected from a plasma burner and an electron beam gun and the second treatment chamber comprises an electron beam gun or a plasma burner as a heat source.

13. The apparatus according to claim 12, wherein the transfer channel rises from the one treatment chamber into the other treatment chamber.

14. The method according to claim 2, comprising the steps:
introducing the material to be treated into the first treatment chamber,
heat-treating the material in the first treatment chamber at a pressure of >10 mbar so that the material is converted into or maintained in a liquid state,
transferring the liquid material into the second treatment chamber,
heat-treating of the liquid material in the second treatment chamber at a pressure of up to 10 mbar,
wherein the transfer of the liquid material from the first treatment chamber into the second treatment chamber is conducted by a transfer channel which connects both treatment chambers and facilitates a continuous flow of the liquid material.
